(19) United States
(12) Patent Application Publication
(10) Pub. No.: US 2023/0298851 A1
(43) Pub. Date: Sep. 21, 2023

(54) SYSTEMS AND METHODS FOR SIGNAL ELECTRON DETECTION IN AN INSPECTION APPARATUS

(71) Applicant: ASML Netherlands B.V., Veldhoven (NL)

(72) Inventors: Chih-Yu JEN, San Jose, CA (US); Chien-Hung CHEN, San Jose, CA (US); Long MA, San Jose, CA (US); Bruno LA FONTAINE, Pleasanton, CA (US); Datong ZHANG, San Jose, CA (US)

(73) Assignee: ASML Netherlands B.V., Veldhoven (NL)

(21) Appl. No.: 18/018,578

(22) PCT Filed: Jul. 26, 2021
(86) PCT No.: PCT/EP2021/070780

§ 371 Date: Jan. 29, 2023

Related U.S. Application Data
(60) Provisional application No. 63/058,393, filed on Jul. 29, 2020.

(51) Int. Cl. H01J 37/244; H01J 37/28

(52) U.S. Cl. CPC H01J 37/244; H01J 37/28; H01J 2237/24475; H01J 2237/2815; H01J 2237/24495; H01J 2237/2611

(57) ABSTRACT

A charged particle beam apparatus for inspecting a sample is provided. The apparatus includes a pixelized electron detector to receive signal electrons generated in response to an incidence of an emitted charged particle beam onto the sample. The pixelized electron detector includes multiple pixels arranged in a grid pattern. The multiple pixels may be configured to generate multiple detection signals, wherein each detection signal corresponds to the signal electrons received by a corresponding pixel of the pixelized electron detector. The apparatus further includes a controller includes circuitry configured to determine a topographical characteristic of a structure within the sample based on the detection signals generated by the multiple pixels, and identifying a defect within the sample based on the topographical characteristic of the structure of the sample.

### CROSS-REFERENCE TO RELATED APPLICATIONS

This application claims priority of U.S. application 63/058,393 which was filed on Jul. 29, 2020 and which is incorporated herein in its entirety by reference.

### TECHNICAL FIELD

The embodiments provided herein disclose a charged-particle beam apparatus, and more particularly improved systems and methods for signal electron detection.

### BACKGROUND

When manufacturing semiconductor integrated circuit (IC) chips, undesired pattern defects, as a consequence of, for example, optical effects and incidental particles, inevitably occur on a substrate (i.e., wafer) or a mask during the fabrication processes, thereby reducing the yield. Monitoring the extent of the undesired pattern defects is therefore an important process in the manufacture of IC chips. More generally, the inspection or measurement of a surface of a substrate, or other object/material, is an important process during and after its manufacture.

Pattern inspection tools with a charged particle beam have been used to inspect objects, for example to detect pattern defects. These tools typically use electron microscopy techniques, such as a scanning electron microscope (SEM). In a SEM, a primary electron beam of electrons at a relatively high energy is targeted with a final deceleration step in order to land on a sample at a relatively low landing energy. The beam of electrons is focused as a probing spot on the sample. The interactions between the material structure at the probing spot and the landing electrons from the beam of electrons cause electrons to be emitted from the surface, such as secondary electrons, backscattered electrons, or Auger electrons (collectively called “signal electrons”). The signal electrons may be emitted from the material structure of the sample. By scanning the primary electron beam as the probing spot over the sample surface, signal electrons may be emitted across the surface of the sample. By collecting these emitted signal electrons from the sample surface, a pattern inspection tool may obtain an image representing characteristics of the material structure of the sample.

### SUMMARY

The embodiments provided herein disclose a charged-particle beam apparatus, and more particularly improved systems and methods for signal electron detection.

One aspect of the present disclosure is directed to a method for inspecting a sample using a charged particle beam apparatus having a pixelized electron detector with multiple pixels. The method may comprise receiving signal electrons by the multiple pixels of the pixelized electron detector, wherein the signal electrons are generated in response to an incidence of an emitted charged particle beam onto the sample. The method may also comprise generating detection signals based on the signal electrons received by the multiple pixels, wherein each detection signal corresponds to the signal electrons received by a corresponding pixel of the pixelized electron detector and determining a topographical characteristic of a structure within the sample based on the detection signals, wherein the multiple pixels of the pixelized electron detector are arranged in a grid pattern.

Another aspect of the present disclosure is directed to a method for inspecting a sample using a charged particle beam apparatus comprising a segmented electron detector with multiple detection segments. The method may comprise receiving signal electrons by the multiple detection segments, wherein the signal electrons are generated in response to an incidence of an emitted charged particle beam onto the sample. The method may also comprise generating detection signals based on the signal electrons received by the multiple detection segments, wherein each detection signal corresponds to the signal electrons received by a corresponding detection segment of the segmented electron detector and determining a topographical characteristic of a structure within the sample based on the detection signals. The method may further comprise identifying a defect within the sample based on the topographical characteristic of the structure within the sample.

Another aspect of the present disclosure is directed to a charged particle beam apparatus for inspecting a sample comprising a pixelized electron detector to receive signal electrons generated in response to an incidence of an emitted charged particle beam onto the sample. The pixelized electron detector may comprise multiple pixels arranged in a grid pattern and configured to generate multiple detection signals, wherein each detection signal corresponds to the signal electrons received by a corresponding pixel of the pixelized electron detector. The charged particle beam apparatus may also comprise a controller includes circuitry configured to determine a topographical characteristic of a structure within the sample based on the detection signals generated by the multiple pixels and identify a defect within the sample based on the topographical characteristic of the structure of the sample.

Another aspect of the disclosure is directed to a charged particle beam apparatus for inspecting a sample comprising a segmented electron detector to receive signal electrons generated in response to an incidence of an emitted charged particle beam onto the sample. The segmented electron detector may comprise multiple detection segments configured to generate multiple detection signals, wherein each detection signal corresponds to the signal electrons received by a corresponding detection segment of the segmented electron detector. The charged particle beam apparatus may also comprise a controller includes circuitry configured to determine a topographical characteristic of a structure within the sample based on the detection signals generated by the multiple pixels and identify a defect within the sample based on the topographical characteristic of the structure of the sample.

Another the disclosure is directed to an electron detector for detecting signal electrons. The electron detector may comprise multiple pixels which are arranged in a grid pattern on a surface of the electron detector, configured to receive the signal electrons generated from a sample in response to an incidence of an emitted charged particle beam onto the sample, and configured to generate multiple detection signals. Each detection signal may correspond to the signal electrons received by a corresponding pixel of the electron detector. The multiple detection signals may enable determining a topographical characteristic of a structure within the sample.

Other advantages of the embodiments of the present disclosure will become apparent from the following description taken in conjunction with the accompanying drawings wherein are set forth, by way of illustration and example, certain embodiments of the present disclosure.

### BRIEF DESCRIPTION OF FIGURES

FIG. 1A is an illustration showing a sample inspection process using a conventional electron detector.

FIG. 1B is an illustration showing a sample inspection process using an improved electron detector, consistent with embodiments of the present disclosure.

FIG. 1C is a schematic diagram illustrating a charged-particle beam inspection system, consistent with embodiments of the present disclosure.

FIG. 2 is a schematic diagram illustrating an exemplary configuration of an electron beam tool that can be a part of the charged-particle beam inspection system of FIG. 1C, consistent with embodiments of the present disclosure.

FIGS. 3A-3C are schematic diagrams showing an exemplary charged-particle beam apparatus comprising a plurality of signal electron detectors, consistent with embodiments of the present disclosure.

FIGS. 4A-4C illustrate an exemplary signal electron detector and its operations, consistent with embodiments of the present disclosure.

FIGS. 5A-5D are illustrative diagrams showing an exemplary inspection process using the signal electron detector of FIG. 4A, consistent with embodiments of the present disclosure.

FIGS. 6A and 6B are illustrative diagrams showing an exemplary inspection process using the signal electron detector of FIG. 4A, consistent with embodiments of the present disclosure.

FIGS. 7A and 7B are illustrative diagrams showing an exemplary inspection process using the signal electron detector of FIG. 4A, consistent with embodiments of the present disclosure.

FIG. 8 illustrates an exemplary method of using the pixelized signal electron detector of FIG. 4A, consistent with embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations. Instead, they are merely examples of apparatuses and methods consistent with aspects related to the disclosed embodiments as recited in the appended claims. For example, although some embodiments are described in the context of utilizing electron beams, the disclosure is not so limited. Other types of charged particle beams may be similarly applied. Furthermore, other imaging systems may be used, such as optical imaging, photo detection, x-ray detection, etc.

Electronic devices are constructed of circuits formed on a piece of silicon called a substrate. Many circuits may be formed together on the same piece of silicon and are called integrated circuits or ICs. The size of these circuits has decreased dramatically so that many more of them can fit on the substrate. For example, an IC chip in a smart phone can be as small as a thumbnail and yet may include over 2 billion transistors, the size of each transistor being less than 1/1000th the size of a human hair.

Making these extremely small ICs is a complex, time-consuming, and expensive process, often involving hundreds of individual steps. Errors in even one step have the potential to result in defects in the finished IC, thereby rendering it useless. Thus, one goal of the manufacturing process is to avoid such defects to maximize the number of functional ICs made in the process, that is, to improve the overall yield of the process.

One component of improving yield is monitoring the chip making process to ensure that it is producing a sufficient number of functional integrated circuits. One way to monitor the process is to inspect the chip circuit structures at various stages of their formation. Inspection can be carried out using a scanning electron microscope (SEM). An SEM can be used to image these extremely small structures, in effect, taking a “picture” of the structures. The image can be used to determine if the structure was formed properly and also if it was formed in the proper location. If the structure is defective, then the process can be adjusted so the defect is less likely to recur.

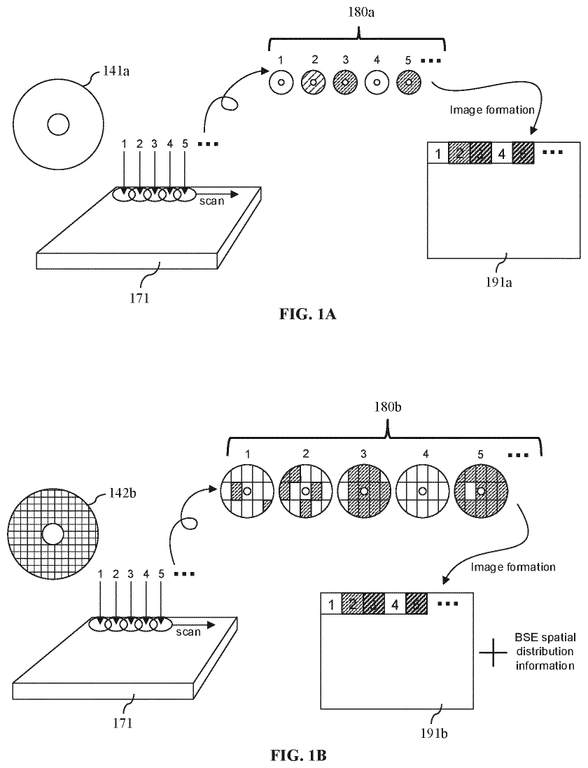

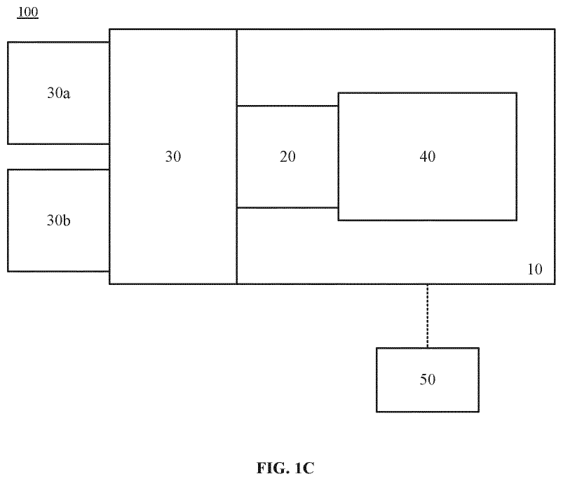

In a conventional inspection system, the images of the IC structures are generated based on the multiple output values produced over time based on signal electrons detected by an electron detector. For example, as shown in FIG. 1A, a conventional inspection system utilizing an SEM technique scans multiple consecutive small parts of a sample 171 over a time period, and takes a series of tiny pictures 180a by detecting signal electrons with an electron detector 141a. A computer processor of the system then processes the series of tiny pictures 180a and reconstructs an output image 191a representing the sample 171. As shown in FIG. 1A, each of tiny pictures 180a conveys only overall information about each scan area (e.g., the overall intensity of the signal electrons received by the whole electron detector), but has a limited capability to capture the information regarding structures within the scan area. To discern extremely small IC structures, each scanning area must be sufficiently reduced. However, smaller scanning area means more time to inspect the whole sample, and therefore impacting the speed of the inspection system.

One aspect of the present disclosure includes an improved electron detector that can capture more information from each scan area without reducing the size of the scan area. For example, FIG. 1B shows a pixelized electron detector 142b comprising multiple pixels that can individually detect the signal electrons and collect the information about the sample, for example, the shape or position of structures within the scan area. Accordingly, each of the series of tiny pictures 180b includes more information, for example the spatial distribution information of the signal electrons which represents the IC structures. An inspection system with the pixelized electron detector 142 can still produce an output image 191b, like the conventional system, along with the additional spatial information. With the reconstructed image and the additionally obtained spatial distribution information, the improve inspection system can identify a very small structural defect without hurting the speed of the inspection system. In some embodiments, the pixelized electron detector 142b may be suited to detect backscattered electrons (BSEs) which are typically generated from deeper subsurface regions of the sample. Collecting the spatial distribution information of BSEs from each scan may provide three-dimensional information of buried structures underneath the sample surface.

Relative dimensions of components in drawings may be exaggerated for clarity. Within the following description of drawings, the same or like reference numbers refer to the same or like components or entities, and only the differences with respect to the individual embodiments are described. As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

Reference is now made to FIG. 1C, which illustrates an exemplary charged particle beam inspection system 100 such as an electron beam inspection (EBI) system, consistent with embodiments of the present disclosure. As shown in FIG. 1C, charged particle beam inspection system 100 includes a main chamber 10, a load-lock chamber 20, an electron beam tool 40, and an equipment front end module (EFEM) 30. Electron beam tool 40 is located within main chamber 10. While the description and drawings are directed to an electron beam, it is appreciated that the embodiments are not used to limit the present disclosure to specific charged particles.

EFEM 30 includes a first loading port 30a and a second loading port 30b. EFEM 30 may include additional loading port(s). First loading port 30a and second loading port 30b receive wafer front opening unified pods (FOUPs) that contain wafers (e.g., semiconductor wafers or wafers made of other material(s)) or samples to be inspected (wafers and samples are collectively referred to as “wafers” hereafter). One or more robot arms (not shown) in EFEM 30 transport the wafers to load-lock chamber 20.

Load-lock chamber 20 is connected to a load/lock vacuum pump system (not shown), which removes gas molecules in load-lock chamber 20 to reach a first pressure below the atmospheric pressure. After reaching the first pressure, one or more robot arms (not shown) transport the wafer from load-lock chamber 20 to main chamber 10. Main chamber 10 is connected to a main chamber vacuum pump system (not shown), which removes gas molecules in main chamber 10 to reach a second pressure below the first pressure. After reaching the second pressure, the wafer is subject to inspection by electron beam tool 40. In some embodiments, electron beam tool 40 may comprise a single-beam inspection tool.

Controller 50 may be electronically connected to electron beam tool 40 and may be electronically connected to other components as well. Controller 50 may be a computer configured to execute various controls of charged particle beam inspection system 100. Controller 50 may also include processing circuitry configured to execute various signal and image processing functions. While controller 50 is shown in FIG. 1C as being outside of the structure that includes main chamber 10, load-lock chamber 20, and EFEM 30, it is appreciated that controller 50 can be part of the structure.

While the present disclosure provides examples of main chamber 10 housing an electron beam inspection system, it should be noted that aspects of the disclosure in their broadest sense, are not limited to a chamber housing an electron beam inspection system. Rather, it is appreciated that the foregoing principles may be applied to other chambers as well.

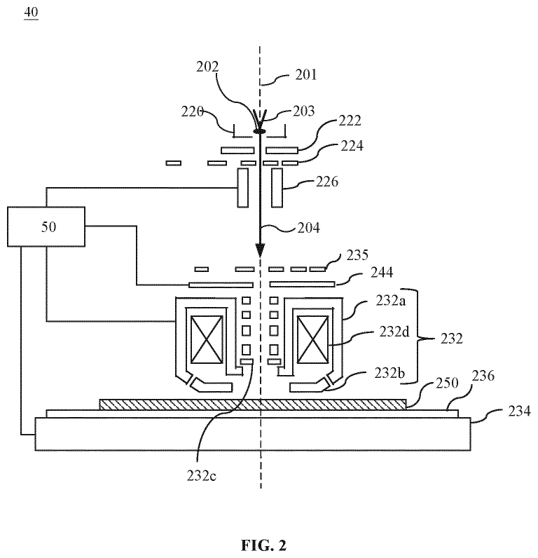

Reference is now made to FIG. 2, which is a schematic diagram illustrating an exemplary configuration of an electron beam tool 40 that can be a part of the charged particle beam inspection system 100 of FIG. 1C, consistent with embodiments of the present disclosure. Electron beam tool 40 (also referred to herein as apparatus 40) may comprise an electron emitter, which may comprise a cathode 203, an anode 220, and a gun aperture 222. Electron beam tool 40 may further include a Coulomb aperture array 224, a condenser lens 226, a beam-limiting aperture array 235, an objective lens assembly 232, and an electron detector 244. Electron beam tool 40 may further include a sample holder 236 supported by motorized stage 234 to hold a sample 250 to be inspected. It is to be appreciated that other relevant components may be added or omitted, as needed.

In some embodiments, electron emitter may include cathode 203, an extractor anode 220, wherein primary electrons can be emitted from the cathode and extracted or accelerated to form a primary electron beam 204 that forms a primary beam crossover 202 (virtual or real). Primary electron beam 204 can be visualized as being emitted from primary beam crossover 202.

In some embodiments, the electron emitter, condenser lens 226, objective lens assembly 232, beam-limiting aperture array 235, and electron detector 244 may be aligned with a primary optical axis 201 of apparatus 40. In some embodiments, electron detector 244 may be placed off primary optical axis 201, along a secondary optical axis (not shown).

Objective lens assembly 232, in some embodiments, may comprise a modified swing objective retarding immersion lens (SORIL), which includes a pole piece 232a, a control electrode 232b, a deflector 232c (or more than one deflectors), and an exciting coil 232d. In a general imaging process, primary electron beam 204 emanating from the tip of cathode 203 is accelerated by an accelerating voltage applied to anode 220. A portion of primary electron beam 204 passes through gun aperture 222, and an aperture of Coulomb aperture array 224, and is focused by condenser lens 226 so as to fully or partially pass through an aperture of beam-limiting aperture array 235. The electrons passing through the aperture of beam-limiting aperture array 235 may be focused to form a probe spot on the surface of sample 250 by the modified SORIL lens and deflected to scan the surface of sample 250 by deflector 232c. Secondary electrons emanated from the sample surface may be collected by electron detector 244 to form an image of the scanned area of interest.

In objective lens assembly 232, exciting coil 232d and pole piece 232a may generate a magnetic field that is leaked out through the gap between two ends of pole piece 232a and distributed in the area surrounding optical axis 201. A part of sample 250 being scanned by primary electron beam 204 can be immersed in the magnetic field and can be electrically charged, which, in turn, creates an electric field. The electric field may reduce the energy of impinging primary electron beam 204 near and on the surface of sample 250. Control electrode 232b, being electrically isolated from pole piece 232a, controls the electric field above and on sample 250 to reduce aberrations of objective lens assembly 232 and control focusing situation of signal electron beams for high detection efficiency. Deflector 232c may deflect primary electron beam 204 to facilitate beam scanning on the wafer. For example, in a scanning process, deflector 232c can be controlled to deflect primary electron beam 204, onto different locations of top surface of sample 250 at different time points, to provide data for image reconstruction for different parts of sample 250.

Backscattered electrons (BSEs) and secondary electrons (SEs) can be emitted from the part of sample 250 upon receiving primary electron beam 204. Electron detector 244 may capture the BSEs and SEs and generate image of the sample based on the information collected from the captured signal electrons. If electron detector 244 is positioned off primary optical axis 201, a beam separator (not shown) can direct the BSEs and SEs to a sensor surface of electron detector 244. The detected signal electron beams can form corresponding secondary electron beam spots on the sensor surface of electron detector 244. Electron detector 244 can generate signals (e.g., voltages, currents) that represent the intensities of the received signal electron beam spots, and provide the signals to a processing system, such as controller 50. The intensity of secondary or backscattered electron beams, and the resultant beam spots, can vary according to the external or internal structure of sample 250. Moreover, as discussed above, primary electron beam 204 can be deflected onto different locations of the top surface of sample 250 to generate secondary or backscattered signal electron beams (and the resultant beam spots) of different intensities. Therefore, by mapping the intensities of the signal electron beam spots with the locations of primary electron beam 204 on sample 250, the processing system can reconstruct an image of sample 250 that reflects the internal or external structures of sample 250.

In some embodiments, controller 50 may comprise an image processing system that includes an image acquirer (not shown) and a storage (not shown). The image acquirer may comprise one or more processors. For example, the image acquirer may comprise a computer, server, mainframe host, terminals, personal computer, any kind of mobile computing devices, and the like, or a combination thereof. The image acquirer may be communicatively coupled to electron detector 244 of apparatus 40 through a medium such as an electrical conductor, optical fiber cable, portable storage media, IR, Bluetooth, internet, wireless network, wireless radio, among others, or a combination thereof. In some embodiments, the image acquirer may receive a signal from electron detector 244 and may construct an image. The image acquirer may thus acquire images of regions of sample 250. The image acquirer may also perform various post-processing functions, such as generating contours, superimposing indicators on an acquired image, and the like. The image acquirer may be configured to perform adjustments of brightness and contrast, etc. of acquired images. In some embodiments, the storage may be a storage medium such as a hard disk, flash drive, cloud storage, random access memory (RAM), other types of computer readable memory, and the like. The storage may be coupled with the image acquirer and may be used for saving scanned raw image data as original images, and post-processed images.

In some embodiments, controller 50 may include measurement circuitries (e.g., analog-to-digital converters) to obtain a distribution of the detected secondary electrons. The electron distribution data collected during a detection time window, in combination with corresponding scan path data of a primary beam 204 incident on the sample (e.g., a wafer) surface, can be used to reconstruct images of the wafer structures under inspection. The reconstructed images can be used to reveal various features of the internal or external structures of sample 250, and thereby can be used to reveal any defects that may exist in sample 250 (such as wafer).

In some embodiments, controller 50 may control motorized stage 234 to move sample 250 during inspection. In some embodiments, controller 50 may enable motorized stage 234 to move sample 250 in a direction continuously at a constant speed. In other embodiments, controller 50 may enable motorized stage 234 to change the speed of the movement of sample 250 over time depending on the steps of scanning process.

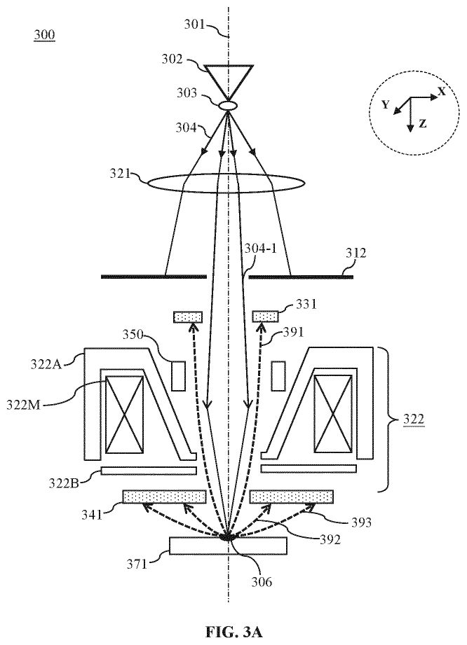

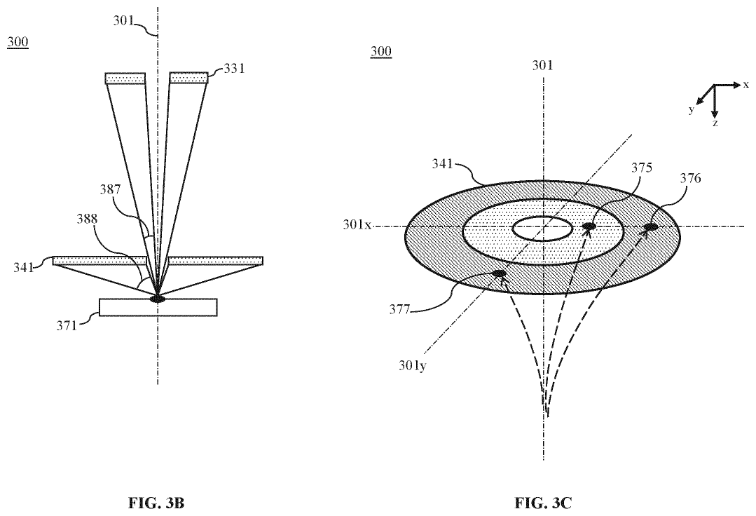

Reference is now made to FIGS. 3A-3C, which are schematic diagrams showing a charged-particle beam apparatus comprising a plurality of signal electron detectors, consistent with embodiments of the present disclosure. In SEMs, apparatus 300 may comprise an electron source 302 configured to emit primary electrons from a cathode (e.g., cathode 203 of FIG. 2) and form a primary electron beam 304 that emanates from a primary beam crossover 303 (virtual or real) along a primary optical axis 301. Apparatus 300 may further comprise a condenser lens 321, a beam-limiting aperture array 312, an in-lens electron detector 331, a backscattered electron detector 341, a scanning deflection unit 350, and an objective lens assembly 322. In the context of this disclosure, an in-lens electron detector refers to a charged-particle detector (e.g., electron detector) located inside or above objective lens assembly 322 and may be arranged rotationally symmetric around the primary optical axis (e.g., primary optical axis 301). In some embodiments, an in-lens electron detector may also be referred to as a through-the lens detector, an immersion lens detector, a top detector, or an upper detector. Similarly, the backscattered electron detector 341 may be referred to as a bottom detector or a lower detector. It is to be appreciated that relevant components may be added or omitted or reordered, as appropriate.

As shown in FIG. 3A, primary electron beam 304 may be emitted from electron source 302 and accelerated to a higher energy by an anode (e.g., anode 220 of FIG. 2). A gun aperture (e.g., gun aperture 222 of FIG. 2) may limit the current of primary electron beam 304 to a desired initial value and may work in conjunction with beam-limiting aperture array 312 to obtain a final beam current. Primary electron beam 304 may be focused by condenser lens 321 and objective lens assembly 322 to form a small probe spot 306 on the surface of a sample 371. In some embodiments, the focusing power of condenser lens 321 and the opening size of an aperture of beam-limiting aperture array 312 may be selected to get a desired probe current and make the probe spot size as small as desired.

To obtain small spot sizes over a large range of probe current, beam-limiting aperture array 312 may comprise multiple apertures having various sizes (not shown). The beam-limiting aperture array 312 may be configured to move so that, based on a desired probe current or a probe spot size, one of the apertures of the aperture array 312 can be aligned with the primary optical axis 301. For example, as shown in FIG. 3A, an aperture of the aperture array 312 may be configured to generate primary electron beamlet 304-1 by blocking peripheral electrons of primary electron beam 304. In some embodiments, scanning deflection unit 350 may include one or more deflectors configured to deflect primary electron beamlet 304-1 to scan a desired area on the surface of sample 371.

Apparatus 300 may comprise condenser lens 321 configured to focus primary electron beam 304 so that a portion 304-1 thereof may pass through an on-axis aperture of beam-limiting aperture array 312. Condenser lens 321 may be substantially similar to condenser lens 226 of FIG. 2 and may perform similar functions. Condenser lens 321 may comprise an electrostatic, a magnetic, or a compound electromagnetic lens, among others. Condenser lens 321 may be electrically or communicatively coupled with a controller, such as controller 50 illustrated in FIG. 2. The controller may apply an electrical excitation signal to condenser lens 321 to adjust the focusing power of condenser lens 321 based on factors such as the operation mode, application, desired analysis, or sample material being inspected, among other things.

In some embodiments, objective lens assembly 322 may comprise a compound electromagnetic lens including a magnetic lens 322M and an electrostatic lens formed by an inner pole piece 322A (similar to pole piece 232a of FIG. 2), and a control electrode 322B (similar to control electron 232b of FIG. 2), which work in conjunction to focus primary electron beam 304 at sample 371.

Apparatus 300 may further comprise scanning deflection unit 350 configured to dynamically deflect primary electron beam 304 or primary electron beamlet 304-1 on surface of sample 371. The dynamic deflection of primary electron beamlet 304-1 may enable a desired area or a desired region of interest to be scanned, for example in a raster scan pattern, to generate SEs and BSEs for sample inspection. Scanning deflection unit 350 may comprise one or more deflectors (not shown) configured to deflect primary electron beamlet 304-1 in the X-axis or Y-axis. As used herein, X-axis and Y-axis form Cartesian coordinates, and primary electron beam 304 propagates along primary optical axis 301 which is aligned with Z-axis. X-axis refers to the horizontal axis or the lateral axis extending along the width of the paper, and Y-axis refers to the vertical axis extending in-and-out of the plane of the paper.

As described earlier with respect to FIG. 2, interaction of electrons of primary electron beamlet 304-1 with sample 371 may generate SEs and BSEs. As is commonly known in the art, the emission of SEs and BSEs obeys Lambert's law and has a large energy spread—the electrons emerging from different depths of sample 371 have different emission energies. For example, SEs originate from the surface or the near-surface region of the sample 371 and have lower emission energies (e.g., lower than 50 eV). SEs may be useful in providing information about surface or near-surface features and geometries. On the other hand, BSEs may be generated by elastic scattering events of the incident electrons from deeper subsurface regions of sample 371, and may have higher emission energies in comparison to SEs, in a range from 50 eV to approximately the landing energy of the incident electrons. BSEs may provide compositional information of the material being inspected. The number of BSEs generated may depend on factors such as the atomic number of the material in the sample or the landing energy of primary electron beam, among other things.

In addition to focusing primary electron beam 304 on the surface of sample 371, objective lens assembly 322 may be further configured to focus the signal electrons on the surface of detector 331. As described earlier with respect to sample 250 of FIG. 2, sample 371 may be immersed in a magnetic field of objective lens assembly 322, and the magnetic field may focus the signal electrons with lower energies faster than the signal electrons with higher energies. For example, because of SE's low emission energy, objective lens assembly 322 may be able to strongly focus the SEs (such as along electron path 391) so that a large portion of the SEs land on a detection layer of in-lens detector 331. In contrast to SEs, objective lens assembly 322 may only be able to weakly focus BSEs due to their high emission energies. Accordingly, although some BSEs with small emission angles may travel along electron paths 391 and be detected by in-lens electron detector 331, the BSEs with large emission angles, for example electrons on paths 392 and 393, may not be able to be detected by in-lens electron detector 331.

In some embodiments, an additional electron detector, such as backscattered electron detector 341, can be used to detect those BSEs with large emission angles (e.g., electrons travelling on paths 392 and 393). In the context of this disclosure, an emission polar angle is measured with reference to primary optical axis 301, which is substantially perpendicular to sample 371. As shown in FIG. 3A, the emission polar angle of electrons in path 391 is smaller than the emission polar angles of electrons in paths 392 and 393. Backscattered electron detector 341 may be placed between objective lens assembly 322 and sample 371, and in-lens electron detector 331 may be placed between objective lens assembly 322 and condenser lens 321, allowing the detection of SEs as well as BSEs.

FIG. 3B shows the emission angle ranges of the signal electrons that can be captured by the in-lens electron detector 331 and the backscattered electron detector 341. As explained earlier, the in-lens electron detector 331 (also known as a top detector) may collect the signal electrons having smaller emission angles, within range 387, and traveling close to the primary optical axis 301. On the other hand, the backscattered electron detector 341 (also known as a bottom detector) may collect the signal electrons having larger emission angles, within range 388. In some embodiments, the backscattered electron detector 341 may demonstrate a higher collection efficiency benefitting from the relative short distance from the sample 371 to the detector surface. Accordingly, the backscattered electron detector 341 may serve well for the detection of BSEs which provide, in general, lower yield than SEs.

Although detection efficiency of BSEs could be increased with the backscattered electron detector 341, the information that could be extracted from BSEs are not fully utilized. For example, the higher efficiency achieved from the addition of the backscattered electron detector 341 mostly resulted from the additional detection surface area. In other words, without the backscattered electron detector 341, the BSEs that are emitted with emission angles within range 388 would not have been detected.

The emission of BSEs is understood to be highly dependent upon the atomic number (Z) of the sample material. For example, a layer of heavy element (higher Z) within the sample may backscatter electrons more strongly than a layer of light element (lower Z). Therefore, a layer made of a heavy element can generate a brighter sphere-shape image, while a light-element layer can generate less bright disc-shape image. In a conventional system, however, the detector 341 counts all BSEs equally regardless of the locations where the BSEs are detected, and thereby each BSE contributes equally to the overall output of the detector 341. Even an improved electron detector with a plurality of detection rings, as shown in FIG. 3C, can differentiate the BSEs only based on the polar emission angles.

FIG. 3C shows apparatus 300 with a conventional backscattered electron detector 341 that includes a plurality of detection rings. BSEs may reach different parts (e.g., 375, 376, 377) of the detection surface, and be detected by different detection rings of the detector 341. For example, BSEs with higher emission angles (such as BSEs traveling on path 393 of FIG. 3A) may hit the part of the detector farther away from the primary optical axis 301 (e.g., part 376) and be detected by an outer detection ring, whereas BSEs with smaller emission angles (such as BSEs traveling on path 392 of FIG. 3A) may hit the part of the detector closer to the primary optical axis 301 (e.g., part 375) and be detected by an inner detection ring. This type of electron detector may be able to capture the contrast and shape differences caused by materials with different atomic number (Z) such that it may identify a small area of a heavy element in a matrix of light material.

Some defects, however, may be caused by incorrect shape, size, or relative position of the structures within the sample made of the same material. This geometry-related defects may not easily be identified when the inspection system is equipped with a detector that can differentiate only low and high angle BSEs. When encountering defects with similar composition but different geometry features, it may be desired to have capability to further differentiate BSEs based on the location information. For example, although the parts 376 and 377 may receive BSEs having similar polar emission angles (the similar distances from the primary optical axis 301), one of the two parts may receive more BSEs because BSEs may be emitted unevenly depending upon the geometry of the structure interacting with the primary electron beam.

In some embodiments, collecting the spatial distribution information of the detected BSEs with respect to two-dimensional Cartesian coordinates (defined by axes 301x and 301y in FIG. 3C) may further enhance the detection efficiency and also provide an improved way to obtain device characteristics of the sample under inspection, e.g., the geometry or topographical characteristics of the structure within the sample or the surface morphology of the sample, among other things. The topographical characteristics may include three-dimensional information, such as size (e.g., width, length, depth, etc.), shape, or relative position of buried structures within the sample.

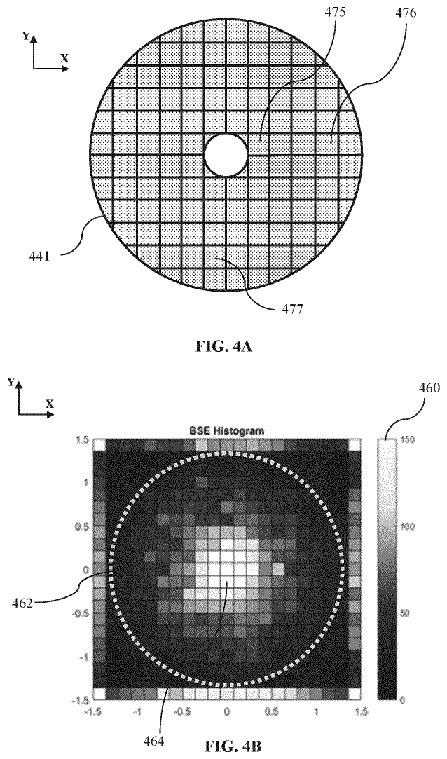

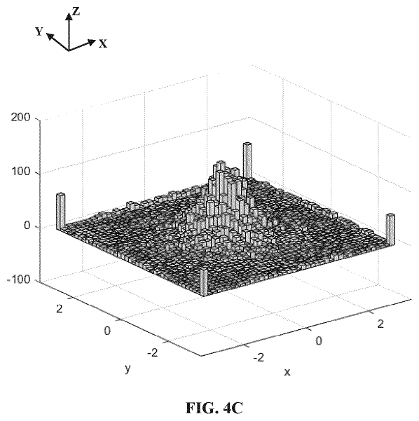

Reference is now made to FIG. 4A, which shows an example of a pixelized signal electron detector 441, consistent with embodiments of the present disclosure. In some embodiments, the pixelized signal electron detector 441 may comprise a plurality of detection segments, which are arranged in a grid on a two-dimensional Cartesian coordinate system defined by two perpendicular axes X and Y-pixels, and configured to generate the spatial distribution information of the signal electrons emitted from the sample. The pixelized signal electron detector 441 may be used in an inspection system (such as the charged-particle beam apparatus 300 of FIGS. 3A-3C).

In some embodiments, each pixel may be configured to generate its own detection signal that represent the intensity of signal electrons (such as SEs or BSEs) received by that particular pixel. Each pixel may also be configured to count the number of signal electrons received by that particular pixel. In some embodiments, a distribution characteristic can be generated based on the number of signal electrons counted by each pixel of the pixelized electron detector. Thus, the pixelized signal electron detector 441 can (i) generate a collective set of detection signals from the multiple pixels conveying the spatial information of the signal electrons emitted from the sample, and (ii) still also produce, like a conventional electron detector, an overall intensity of the signal electrons from a particular scan area on the sample by aggregately processing the multiple detection signals generated by the pixels. This overall intensity information may be used for scanned image reconstruction.

In some embodiments, a bottom detector, such as the backscattered electron detector 341 of the apparatus 300 in FIGS. 3A-3C, may utilize pixelized signal electron detector 441 to collect the spatial distribution information of BSEs. Each pixel, such as pixel 475, 476, and 477, can detect and count the number of BSEs received. In some embodiments, a pixel is configured to generate a detection signal proportional to the number of BSEs counted. For example, the pixel 476 may be used to detect and count BSEs emitted with very high polar emission angles, such as incoherently scattered electrons (Rutherford scattered from the nucleus of the atoms of the sample), whereas the pixel 475 may be used to detect and count BSEs with smaller polar emission angles (with the same y-value), such as directly back-scattered electrons. Similarly, although BSEs arriving at pixels 476 and 477 have similar polar emission angles, the pixel 477 may be used to detect and count BSEs emitted in a different direction (−y direction) than the pixel 476 (+x direction).

It is appreciated that the detection segments can be arranged in a different manner. For example, the detection segments of the signal electron detector 441 may be arranged radially, circumferentially, or azimuthally around a center of the detector through which a primary optical axis (such as primary optical axis 301 of FIG. 3A) passes.

Reference is now made to FIGS. 4B and 4C, which illustrate an operation of the pixelized signal electron detector 441 of FIG. 4A, consistent with embodiments of the present disclosure. FIG. 4B shows an exemplary histogram illustrating the spatial distribution information of the signal electrons received by multiple pixels of a pixelized signal electron detector. The squares illustratively represent the pixels of the pixelized electron detector, and the grayscale color illustratively represents the intensity (e.g., the count) of signal electrons received by that particular pixel. As shown by the spectrum scale 460, the color white represents the highest number of signal electrons and the color black represents the lowest number of the signal electrons. For example, in this exemplary case, the pixel 464 may have detected high number of signal electrons, while the pixel 462 may have detected only small number of signal electrons. FIG. 4C shows a three-dimensional representation of the same spatial distribution information of the signal electrons from the sample. The plane defined by the X and Y axes represents the surface of the pixelized signal electron detector. The Z axis represent the number of signal electrons detected by the pixels.

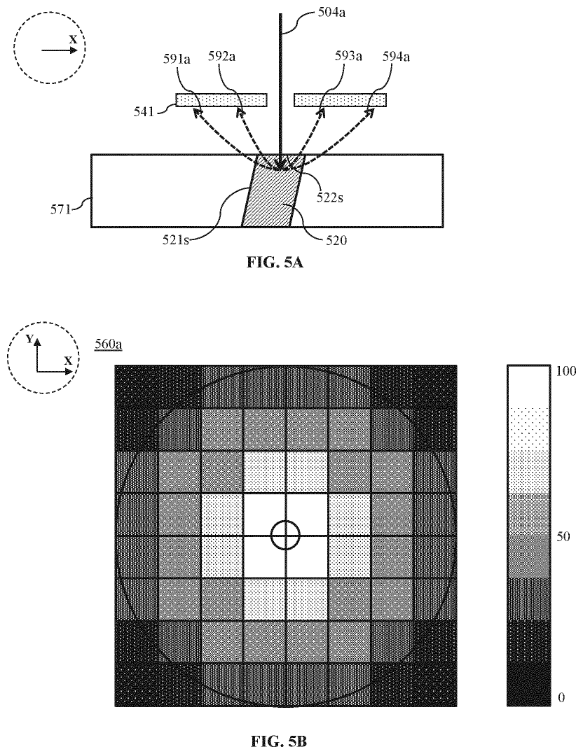

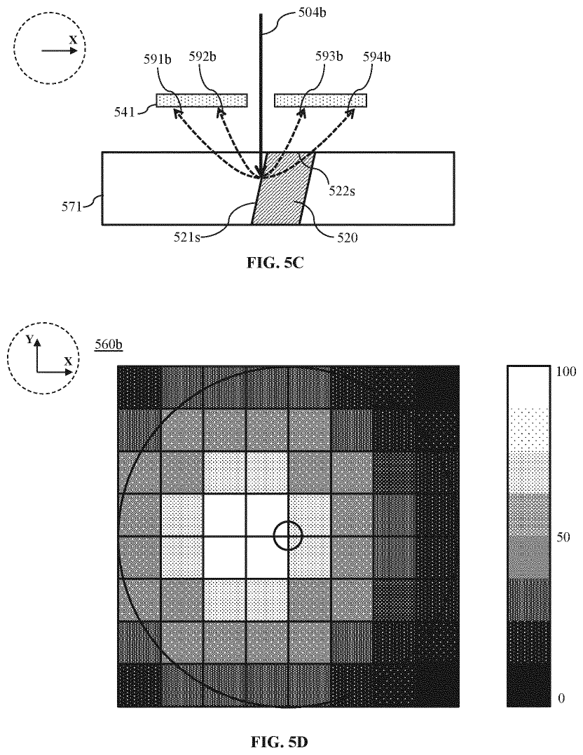

Reference is now made to FIGS. 5A-5D, which are illustrative diagrams showing an exemplary inspection process using a pixelized signal electron detector (such as the pixelized signal electron detector 441 of FIG. 4A), consistent with embodiments of the present disclosure.

As described above with respect to FIG. 3C and FIG. 4A, some defects caused by incorrect shape, size, or relative position of the structures within the sample are difficult to identify just using reconstructed images, and accordingly an inspection system may be desired to collect additional spatial information representing the topographical information of the structures within the sample.

FIG. 5A shows an example of a geometry-related defect buried within a sample 571 including an embedded structure 510, e.g., an embedded tungsten plug. In some cases, a sidewall 521s of the embedded structure 510 is unwantedly tilted. When a primary electron beam 504a hits the top of the embedded structure, as shown in FIG. 5A, signal electrons would be emitted evenly around the primary optical axis—the intensity of signal electrons would decrease evenly as the distance from the primary optical axis increase. Thus, as shown in a corresponding histogram 560a in FIG. 5B, pixels around the center may detect the maximum number of signal electrons, while the pixels close to the periphery of the electron detector 541 may receive the minimum number of signal electron. The distribution of the detected signal electrons may be close to a Gaussian distribution around the center of the detector.

However, when the probe spot is moved closer to the tilted sidewall 521s, as shown in FIG. 5C, the signal electrons may be emitted unevenly. For example, because the sidewall 521s is tilted toward the −x direction, more signal electrons may be emitted toward the −x direction (e.g., more through the path 591b/592b than 593b/594b), resulting in more signal electrons being detected by the pixels in the left portion of the detector. This uneven distribution characteristic is illustrated in a histogram 560b in FIG. 5D. The point where the most signal electrons are detected (i.e., the peak of the Gaussian curve) is shifted toward the −x direction. A conventional electron detector may not be able to discern this slight change in BSE distribution. By processing and comparing the spatial distribution characteristics of the emitted signal electrons using a processor (such as the controller 50 of FIG. 2), the inspection system can identify the structure 520 which has a defectively tilted sidewall 521s.

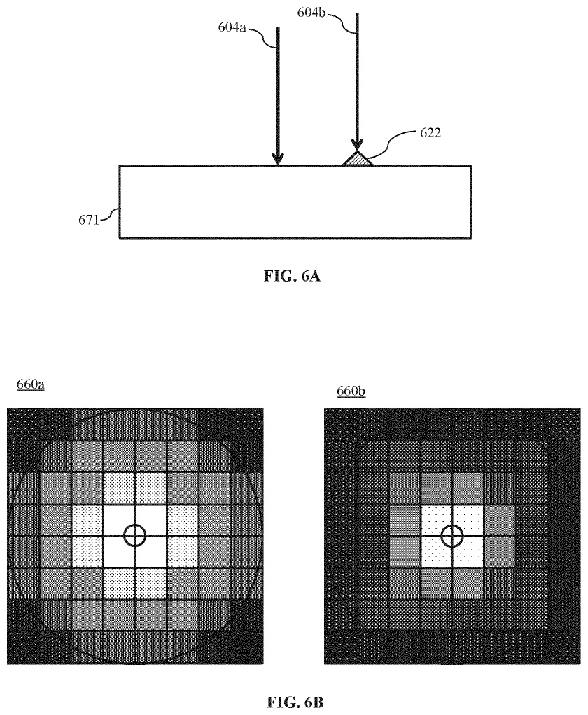

Reference is now made to FIGS. 6A and 6B, which are illustrative diagrams showing an exemplary inspection process using the signal electron detector of FIG. 4A, consistent with embodiments of the present disclosure. The pixelized signal electron detector may be utilized for producing surface morphology information. As described above, when inspecting a sample made of a single material, the signal electron distribution may vary depending upon the morphology of the surface structure.

FIG. 6A shows a silicon wafer sample 671 having a SiO₂ bump 622 which may have been accumulated on the surface of the silicon wafer sample 671. The distribution characteristics of signal electrons will be different when the primary electron beam 604a hits the top surface of the sample 671 and the primary electron beam 604b hits the SiO₂ bump 622.

FIG. 6B shows corresponding histograms from the pixelized detector. Histogram 660a illustratively represents a BSE distribution characteristic from the surface of the silicon wafer sample 671. Histogram 660b illustratively represents the BSE distribution characteristic from the SiO₂ bump 622. From the SiO₂ bump, the BSEs are emitted with much smaller polar angles and the pixels showing high intensity detection are more concentrated close to the center of the detector, thereby causing the histogram 660b to show a much narrower Gaussian distribution than the histogram 660a. The distribution information can be provided to a processor (such as the controller 50 of FIG. 2) to obtain topographical information of the surface structures.

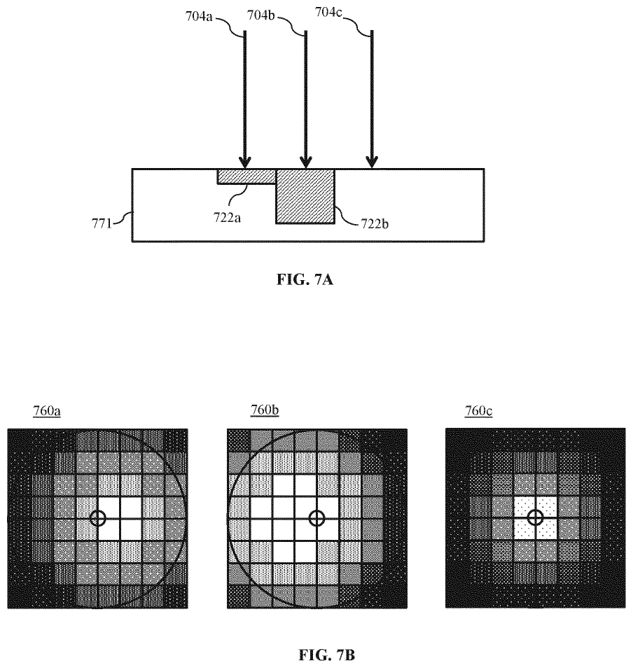

Reference is now made to FIGS. 7A and 7B, which are illustrative diagrams showing an exemplary inspection process using the signal electron detector of FIG. 4A, consistent with embodiments of the present disclosure. One of the advantages having the availability of the spatial distribution information of the signal electrons emitted from a sample is that an inspection system may be able to adopt a bigger probe spot (such as probe spot 306 of FIG. 3A) with a larger pitch (a distance between consecutive scan sampling positions), thereby resulting in an improvement of the overall system inspection throughput.

As illustrated below FIG. 7A, a sample 771 may include a normal tungsten plug 722b as well as a thin tungsten residual layer 722a. This type of small defect—a thin tungsten residual layer 722a—may be difficult to identify using a conventional electron detector unless the probe spot and the pitch size is significantly small. Conventional electron detectors are optimized to form images of the sample with a reasonable resolution for a short period of time (to maintain high throughput). But the smaller probe spot with finer pitch will increase the time needed to scan a given surface area of the sample, thereby reducing the system inspection throughput. Therefore, using a smaller probe spot with a finer pitch would make the inspection system unsuitable for high-throughput inspection.

A pixelized electron detector can distinguish the thin tungsten residual layer 722a by collecting the spatial distribution characteristics based on the individual intensity values from multiple pixels. For example, the pixelized electron detector may collect the distribution information of the received BSEs from each of three cases—(i) when primary beam 704a hits the top of the thin tungsten residual layer 722a, (ii) when primary beam 704b hits the top of the normal tungsten plug 722b, and (iii) when primary beam 704c hits the top of the sample 771. FIG. 7B shows three histograms corresponding to those three inspections, respectively. An inspection system with the pixelized electron detector can identify the thin tungsten residual layer 722a by analyzing the distribution characteristics. First, as shown in histograms 760a and 760b, the overall yield of signal electrons (e.g., BSEs) may be reduced from the thin residual layer 722a compared to the normal tungsten plug 722b.

Furthermore, for the thin layer 722a, the yield of the signal electrons (e.g., BSEs) may be slightly higher in a side close to the normal tungsten plug 722b (i.e., the right-hand side of the layer 722a) because some of the forward-scattered electrons from the right-hand side of the thin residual layer 722a could be backscattered toward the electron detector by the normal tungsten plug 722b, whereas most of the forward-scattered electrons from the left-hand side of the thin residual layer 722a (which is adjacent to substrate SiO₂) may be less likely be backscattered toward the electron detector. Similarly, for the normal tungsten plug 722b, the yield of the signal electrons may be imbalanced toward the thin residual layer 722a (i.e., the left-hand side of the plug 722b). Accordingly, detecting the BSE distribution imbalance may provide further information to determine a topographical characteristic of the structures within the sample (e.g., the thin residual layer 722a, the normal tungsten plug 722b). Comparing those distribution characteristics against the distribution characteristic from the sample itself, as shown in the histogram 760c, may enable an inspection tool to identify the small defect like the thin residual tungsten layer 722a without sacrificing the throughput of the system.

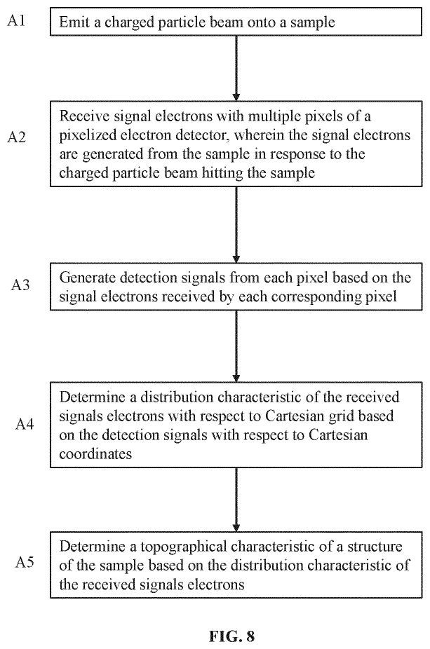

Reference is now made to FIG. 8, which illustrates an exemplary method of using the pixelized signal electron detector of FIG. 4A, consistent with embodiments of the present disclosure. The method may be performed by an electron beam inspection tool (such as electron beam tool 40 of FIG. 2) including an image processor (such as controller 50 of FIG. 2).

In step A1, the electron beam inspection tool delivers a charged particle beam (such as a primary electron beam 204 of FIG. 2) to a sample (such as sample 250 of FIG. 2) to scan an area of the sample. In response to the incidence of the primary electron beam onto the sample, signal electrons (SEs and BSEs) may be generated from the sample.

In step A2, a signal electron detector (such as detectors 331 and 341) receives the signal electrons generated from the sample. In some embodiments, the signal electron detector may be a pixelized signal electron detector (such as pixelized signal electron detector 441 of FIG. 4A) comprising a plurality pixels that are arranged in a grid on a two-dimensional Cartesian coordinate system defined by two perpendicular axes X and Y. The pixelized signal electron detector may be configured to generate the spatial distribution information of the signal electrons based on the intensities of the signal electron received by the pixels.

In step A3, the signal electron detector generates multiple detection signals based on the received signal electrons. In some embodiments, each pixel of the signal electron (such as the pixelized electron detector 441 of FIG. 4A) may be configured to generate its own detection signal that represent the intensity of signal electrons (such as SEs or BSEs) received by that particular pixel. Thus, the pixelized signal electron detector 441 can (i) generate a collective set of detection signals from the multiple pixels conveying the spatial information of the signal electrons emitted from the sample, and (ii) still also produce, like a conventional electron detector, an overall intensity of the signal electrons from a particular scan area on the sample by aggregately processing the multiple detection signals generated by the pixels. In some embodiments, each pixel is configured to count a number of signal electrons received by the pixel and to generate a detection signal proportional to the number of signal electrons counted.

In step A4, the image processor (such as controller 50 of FIG. 2) analyzes the detection signals from the multiple pixels and produces a distribution characteristic of the received signal electrons. In some embodiments, the distribution characteristic information may comprise data from the pixels with respect to Cartesian coordinates.

In step A5, the image processor determines a topographical characteristic of the sample based on the distribution characteristic of the received signal electrons. In some embodiments, the topographical characteristic may show a structure buried within the sample (e.g., a tungsten plug 520 shown in FIG. 5A). For example, when the primary electron beam hits a tilted surface (such as the tilted sidewall 521s in FIG. 5A), the signal electrons may be emitted unevenly. Because the surface is tilted toward a certain direction, more signal electrons may be emitted toward that particular direction, resulting in more signal electrons being detected by the pixels positioned in that direction. This uneven distribution characteristic, as shown in a histogram 560b of FIG. 5D, can be used to detect the unwanted shape of the structure within the sample or on the surface of the sample. By processing and comparing the spatial distribution characteristics of the emitted signal electrons with the processor, the inspection system can identify the defectively tilted structure, such as the tilted sidewall 521s in FIG. 5A.

In some embodiments, the topographical characteristic may show a structure on the surface of the sample (e.g., a SiO₂ bump 622 shown in FIG. 6A). The pixelized signal electron detector may be utilized for producing surface morphology information. For example, a structure on the surface of the sample (such as a SiO₂ bump 622 on the surface of a silicon wafer sample 671 of FIG. 6A) may be identified by analyzing the distribution characteristics of signal electrons.

Aspects of the present disclosure are set out in the following numbered clauses:
1. A method for inspecting a sample using a charged particle beam apparatus comprising a pixelized electron detector with multiple pixels, the method comprising:
receiving signal electrons by the multiple pixels of the pixelized electron detector, wherein the signal electrons are generated in response to an incidence of an emitted charged particle beam onto the sample;
generating detection signals based on the signal electrons received by the multiple pixels, wherein each detection signal corresponds to the signal electrons received by a corresponding pixel of the pixelized electron detector; and
determining a topographical characteristic of a structure within the sample based on the detection signals,
wherein the multiple pixels of the pixelized electron detector are arranged in a grid pattern.
2. The method of clause 1, wherein the grid pattern comprises a two-dimensional Cartesian grid.
3. The method of any one of clauses 1-2, further comprising counting a number of the signal electrons received by each of the multiple pixels of the pixelized electron detector.
4. The method of clause 3, wherein the detection signals are generated based on the number of the signal electrons counted by the corresponding pixels.
5. The method of any one of clauses 1-4, wherein determining the topographical characteristic of the structure within the sample includes determining a distribution characteristic of the signal electrons emitted from the sample.
6. The method of clause 5, wherein determining a distribution characteristic is based on the number of the signal electrons counted by each pixel of the pixelized electron detector.
7. The method of any one of clauses 1-6, further comprising identifying a defect within the sample based on the topographical characteristic of the structure within the sample.
8. The method of any one of clauses 1-7, wherein the topographical characteristic of the structure comprises a three-dimensional topographical information of the structure.
9. The method of clause 8, wherein the structure is a buried structure underneath a surface of the sample.
10. The method of clause 10, wherein the three-dimensional topographical information comprises a depth of the structure relative to the surface of the sample.
11. The method of any one of clauses 1-10, wherein the signal electrons comprises backscattered electrons (BSEs).
12. The method of any one of clauses 1-11, wherein each of the multiple pixels of the pixelized electron detector has a same size.
13. The method of any one of clauses 1-12, wherein the charged particle beam comprises a plurality of primary electrons.
14. A method for inspecting a sample using a charged particle beam apparatus comprising a segmented electron detector with multiple detection segments, the method comprising:
receiving signal electrons by the multiple detection segments, wherein the signal electrons are generated in response to an incidence of an emitted charged particle beam onto the sample;
generating detection signals based on the signal electrons received by the multiple detection segments, wherein each detection signal corresponds to the signal electrons received by a corresponding detection segment of the segmented electron detector;
determining a topographical characteristic of a structure within the sample based on the detection signals; and
identifying a defect within the sample based on the topographical characteristic of the structure within the sample.
15. The method of clause 14, wherein the multiple detection segments of the segmented electron detector are arranged in a grid pattern.
16. The method of any one of clauses 14 and 15, wherein the grid pattern comprises a two-dimensional curvilinear grid.
17. The method of any one of clauses 14 and 15, wherein the grid pattern comprises a two-dimensional Cartesian grid.
18. The method of any one of clauses 14-17, further comprising counting a number of the signal electrons received by each of the multiple detection segments of the segmented electron detector.
19. The method of clause 18, wherein the detection signals are generated based on the number of the signal electrons counted by the corresponding detection segments.
20. The method of any one of clauses 14-19, wherein determining the topographical characteristic of the structure within the sample includes determining a distribution characteristic of the signal electrons emitted from the sample.
21. The method of clause 20, wherein determining a distribution characteristic is based on the number of the signal electrons counted by each detection segment of the segmented electron detector.
22. The method of any one of clauses 14-21, wherein the topographical characteristic of the structure comprises a three-dimensional topographical information of the structure.
23. The method of clause 22, wherein the structure is a buried structure underneath a surface of the sample.
24. The method of clause 23, wherein the three-dimensional topographical information comprises a depth of the structure relative to the surface of the sample.
25. The method of any one of clauses 14-24, wherein the signal electrons comprises backscattered electrons (BSEs).
26. The method of any one of clauses 14-25, wherein the charged particle beam comprises a plurality of primary electrons.
27. A charged particle beam apparatus for inspecting a sample, comprising:
a pixelized electron detector to receive signal electrons generated in response to an incidence of an emitted charged particle beam onto the sample, the electron detector comprising:
   multiple pixels arranged in a grid pattern and configured to generate multiple detection signals, wherein each detection signal corresponds to the signal electrons received by a corresponding pixel of the pixelized electron detector; and
a controller includes circuitry configured to:
   determine a topographical characteristic of a structure within the sample based on the detection signals generated by the multiple pixels; and
   identify a defect within the sample based on the topographical characteristic of the structure of the sample.
28. The apparatus of clause 27, wherein the grid pattern comprises a two-dimensional Cartesian grid.
29. The apparatus of any one of clauses 27 and 28, wherein the controller includes circuitry configured to count a number of the signal electrons received by each of the multiple pixels of the pixelized electron detector.
30. The apparatus of clause 29, wherein the multiple detection signals are generated based on the number of the signal electrons counted by the corresponding pixels.
31. The apparatus of any one of clauses 27-30, wherein the controller includes circuitry configured to determine a distribution characteristic of the signal electrons emitted from the sample.
32. The apparatus of clause 31, wherein the determination of the distribution characteristic is based on the number of the signal electrons counted by each pixel of the pixelized electron detector.
33. The apparatus of clause 31, wherein the controller includes circuitry configured to determine a topographical characteristic of a structure within the sample based on the distribution characteristic of the signal electrons emitted from the sample.
34. The apparatus of any one of clauses 27-33, wherein the signal electrons comprises backscattered electrons (BSEs).
35. The apparatus of any one of clauses 27-34, wherein each of the multiple pixels of the pixelized electron detector has a same size.
36. The apparatus of any one of clauses 27-35, wherein the charged particle beam comprises a plurality of primary electrons.
37. A charged particle beam apparatus for inspecting a sample, comprising:
a segmented electron detector to receive signal electrons generated in response to an incidence of an emitted charged particle beam onto the sample, the segmented electron detector comprising:
   multiple detection segments configured to generate multiple detection signals, wherein each detection signal corresponds to the signal electrons received by a corresponding detection segment of the segmented electron detector; and
a controller includes circuitry configured to:
   determine a topographical characteristic of a structure within the sample based on the detection signals generated by the multiple pixels; and
   identify a defect within the sample based on the topographical characteristic of the structure of the sample.
38. The apparatus of clause 37, wherein the controller includes circuitry configured to count a number of the signal electrons received by each of the multiple detection segments of the segmented electron detector.
39. The apparatus of clause 38, wherein the multiple detection signals are generated based on the number of the signal electrons counted by the corresponding detection segments.
40. The apparatus of any one of clauses 37-39, wherein the controller includes circuitry configured to determine a distribution characteristic of the signal electrons emitted from the sample.
41. The apparatus of clause 40, wherein the determination of the distribution characteristic is based on the number of the signal electrons counted by each detection segment of the segmented electron detector.
42. The apparatus of clause 40, wherein the controller includes circuitry configured to determine a topographical characteristic of a structure within the sample based on the distribution characteristic of the signal electrons emitted from the sample.
43. The apparatus of any one of clauses 37-42, wherein the signal electrons comprises backscattered electrons (BSEs).
44. The apparatus of any one of clauses 37-43, wherein the multiple detection segments of the segmented electron detector are arranged in a grid pattern.
45. The apparatus of clause 44, wherein the grid pattern comprises a two-dimensional curvilinear grid.
46. The apparatus of any one of clauses 37-45, wherein the charged particle beam comprises a plurality of primary electrons.
47. An electron detector for detecting signal electrons, comprising multiple pixels:
arranged in a grid pattern on a surface of the electron detector,
configured to receive the signal electrons generated from a sample in response to an incidence of an emitted charged particle beam onto the sample, and
configured to generate multiple detection signals,
wherein each detection signal corresponds to the signal electrons received by a corresponding pixel of the electron detector, and the multiple detection signals enable determining a topographical characteristic of a structure within the sample.
48. The detector of clause 47, wherein the multiple detection signals further enable identifying a defect within the sample based on the topographical characteristic of the structure of the sample.
49. The detector of any one of clauses 47 and 48, wherein the grid pattern comprises a two-dimensional Cartesian grid.
50. The detector of any one of clauses 47-49, wherein the multiple detection signals are generated based on a number of the signal electrons received by the corresponding pixels.
51. The detector of any one of clauses 47-50, wherein the topographical characteristic of the structure within the sample includes a distribution characteristic of the signal electrons emitted from the sample.
52. The method of clause 51, wherein the distribution characteristic is determined based on the number of the signal electrons counted by each pixel of the electron detector.
53. The detector of any one of clauses 47-52, wherein the signal electrons comprises backscattered electrons (BSEs).
54. The detector of any one of clauses 47-53, wherein each of the multiple pixels of the electron detector has a same size.
55. A charged particle beam apparatus for inspecting a sample, comprising:
a pixelized backscattered electron (BSE) detector to receive BSEs generated from the sample after electrons from an electron beam interact with the sample, the pixelized BSE detector comprising multiple pixels arranged in a grid pattern wherein each pixel is configured to receive BSEs that arrive onto that particular pixel; and
a controller includes circuitry configured to determine a characteristic of a structure within the sample based on a distribution of BSEs received amongst the multiple pixels.
56. The apparatus of clause 55, wherein the structure is a buried structure underneath a surface of the sample.
57. The apparatus of clause 56, wherein the characteristic of the structure indicates a depth of the structure relative to the surface of the sample.
58. The apparatus of clause 55, wherein the structure is a surface structure on a surface of the sample.
59. The apparatus of clause 58, wherein the characteristic of the structure indicates topography of the structure.

A non-transitory computer readable medium may be provided that stores instructions for the image processor (such as controller 50 of FIG. 2) to carry out an electron beam generation, signal electron detection, generation of detection signals from the pixels conveying spatial distribution information of the signal electrons, image processing, or other functions and methods consistent with the present disclosure, etc. Common forms of non-transitory media include, for example, a floppy disk, a flexible disk, hard disk, solid state drive, magnetic tape, or any other magnetic data storage medium, a Compact Disc Read Only Memory (CD-ROM), any other optical data storage medium, any physical medium with patterns of holes, a Random Access Memory (RAM), a Programmable Read Only Memory (PROM), and Erasable Programmable Read Only Memory (EPROM), a FLASH-EPROM or any other flash memory, Non-Volatile Random Access Memory (NVRAM), a cache, a register, any other memory chip or cartridge, and networked versions of the same.

It will be appreciated that the embodiments of the present disclosure are not limited to the exact construction that has been described above and illustrated in the accompanying drawings, and that various modifications and changes may be made without departing from the scope thereof. The present disclosure has been described in connection with various embodiments, other embodiments of the invention will be apparent to those skilled in the art from consideration of the specification and practice of the invention disclosed herein. It is intended that the specification and examples be considered as exemplary only, with a true scope and spirit of the invention being indicated by the following claims.

The descriptions above are intended to be illustrative, not limiting. Thus, it will be apparent to one skilled in the art that modifications may be made as described without departing from the scope of the claims set out below.

1. A non-transitory computer readable medium that stores a set of instructions that is executable by at least one processor of a computing device to perform a method for inspecting a sample using a charged particle beam apparatus comprising a pixelized electron detector with multiple pixels, the method comprising:
receiving signal electrons by the multiple pixels of the pixelized electron detector, wherein the signal electrons are generated in response to an incidence of an emitted charged particle beam onto the sample;
generating detection signals based on the signal electrons received by the multiple pixels, wherein each detection signal corresponds to the signal electrons received by a corresponding pixel of the pixelized electron detector; and
determining a topographical characteristic of a structure within the sample based on the detection signals,
wherein the multiple pixels of the pixelized electron detector are arranged in a grid pattern.

2. The computer readable medium of claim 1, wherein the grid pattern comprises a two-dimensional Cartesian grid or a two-dimensional curvilinear grid.

3. The computer readable medium of claim 1, the method further comprising counting a number of the signal electrons received by each of the multiple pixels of the pixelized electron detector.

4. The computer readable medium of claim 3, wherein the detection signals are generated based on the number of the signal electrons counted by the corresponding pixels.

5. The computer readable medium of claim 1, wherein determining the topographical characteristic of the structure within the sample includes determining a distribution characteristic of the signal electrons emitted from the sample.

6. A charged particle beam apparatus for inspecting a sample, comprising:
a pixelized electron detector to receive signal electrons generated in response to an incidence of an emitted charged particle beam onto the sample, the electron detector comprising:
multiple pixels arranged in a grid pattern and configured to generate multiple detection signals, wherein each detection signal corresponds to the signal electrons received by a corresponding pixel of the pixelized electron detector; and
a controller includes circuitry configured to:
determine a topographical characteristic of a structure within the sample based on the detection signals generated by the multiple pixels; and
identify a defect within the sample based on the topographical characteristic of the structure of the sample.

7. The apparatus of claim 6, wherein the grid pattern comprises a two-dimensional Cartesian grid or a two-dimensional curvilinear grid.

8. The apparatus of claim 6, wherein the controller includes circuitry configured to count a number of the signal electrons received by each of the multiple pixels of the pixelized electron detector.

9. The apparatus of claim 8, wherein the multiple detection signals are generated based on the number of the signal electrons counted by the corresponding pixels.

10. The apparatus of claim 6, wherein the controller includes circuitry configured to determine a distribution characteristic of the signal electrons emitted from the sample.

11. The apparatus of claim 10, wherein the determination of the distribution characteristic is based on the number of the signal electrons counted by each pixel of the pixelized electron detector.

12. The apparatus of claim 10, wherein the controller includes circuitry configured to determine a topographical characteristic of a structure within the sample based on the distribution characteristic of the signal electrons emitted from the sample.

13. The apparatus of claim 6, wherein the signal electrons comprises backscattered electrons (BSEs).

14. The apparatus of claim 6, wherein each of the multiple pixels of the pixelized electron detector has a same size.

15. The apparatus of claim 6, wherein the charged particle beam comprises a plurality of primary electrons.

16. The computer readable medium of claim 5, wherein determining a distribution characteristic is based on the number of the signal electrons counted by each pixel of the pixelized electron detector.

17. The computer readable medium of claim 1, further comprising identifying a defect within the sample based on the topographical characteristic of the structure within the sample.

18. The computer readable medium of claim 1, wherein the topographical characteristic of the structure comprises a three-dimensional topographical information of the structure.

19. The computer readable medium of claim 18, wherein the structure is a buried structure underneath a surface of the sample.

20. The computer readable medium of claim 18, wherein the three-dimensional topographical information comprises a depth of the structure relative to the surface of the sample.
